(19) United States
(12) Patent Application Publication
(10) Pub. No.: US 2017/0194204 A1
(43) Pub. Date: Jul. 6, 2017

(54) IMPROVED THROUGH SILICON VIA

(71) Applicant: Ultratech, Inc., San Jose, CA (US)

(72) Inventor: Mark Sowa, Medford, MA (US)

(73) Assignee: Ultratech, Inc., San Jose, CA (US)

(21) Appl. No.: 15/323,805

(22) PCT Filed: Aug. 27, 2014
(86) PCT No.: PCT/US2014/053015

§ 371 Date: Jan. 4, 2017

(51) Int. Cl. H01L 21/768; H01L 21/285; H01L 23/528; H01L 23/48; H01L 23/532

(52) U.S. Cl. CPC H01L 21/76898; H01L 23/481; H01L 23/53238; H01L 23/528; H01L 21/76879; H01L 21/76846; H01L 21/28568; H01L 21/28562; H01L 21/76876

(57) ABSTRACT

Through via holes are prepared for metallization using ALD and PEALD processing. Each via is coated with a titanium nitride barrier layer having a thickness ranging from 20 to 200 Å. A ruthenium sealing layer is formed over the titanium nitride barrier layer wherein the sealing layer is formed without oxygen to prevent oxidation of the titanium nitride barrier layer. A ruthenium nucleation layer is formed over the sealing layer wherein the nucleation layer is formed with oxygen in order to oxidize carbon during the application of the Ru nucleation layer. The sealing layer is formed by a PEALD method using plasma excited nitrogen radicals instead of oxygen.

### 1. FIELD OF THE INVENTION

The present invention relates to preparing internal surfaces of a through-silicon-via for metallization. In particular an inside diameter surface and a base wall surface of each through via is coated with a low resistivity diffusion barrier layer to prevent diffusion of dissimilar materials there through. A sealing layer is applied over the diffusion barrier layer to prevent oxidation of the barrier layer. A nucleation layer is applied over the sealing layer. The nucleation layer promotes crystal nucleation of the metal core and reduces void formation during metallization.

### 2. THE RELATED ART

Through silicon vias are used in multilayer or three dimensional integrated circuits (IC) to electrically inter-connect isolated circuit layers separated from each other by electrically insulating dielectric layers. Through-silicon-vias or through hole vias comprise holes passing through one or more substrate layers which are metallized by filling the hole with a low resistivity material such as copper by electroless deposition or electrochemical plating or similar metallization techniques. The demand for fabricating cheaper, smaller and lighter electronic products with better performance is driving the need to product smaller via holes distributed over the circuit landscape with a smaller hole pitch. This has led to the need to provide via holes having a diameter in the range of 12-30 μm with a through hole depth or length of 200-600 μm. Such via holes are generally referred to as high aspect ratio via holes with a hole depth to diameter ratio of greater than about 10 ranging up to 50.

Via holes are formed by a wet etch, an electrochemical etch, by laser drilling, and more recently by ion beam milling or etching such as a deep reactive ion etching (DRIE). The via holes pass entirely through a silicon substrate and leave exposed internal silicon walls as formed. Since the via holes pass completely through the substrate layer a base wall of the via hole is bounded by a conductive portion of a circuit layer attached to or formed integral with the dielectric substrate layer. The holes are then filled (metallization) with a conductive material, e.g. copper, tungsten, polysilicon, gold, or the like, by electroplating, or the like, and the conductive material provides a pathway for electrical communication between circuit layers separated by high resistivity substrate layers.

A critical performance criterion of a through-silicon-via is that the metallization or conductive core provides substantially uniform unrestricted current flow over the entire diameter and along the entire length of the conductive core. Factors that inhibit current flow or otherwise degrade via performance include void formation in the fill material and non-uniform material properties (e.g. non-uniform resistivity). Void formation is especially problematic at boundaries between dissimilar materials where metal crystallization is non-uniform. Non-uniform material properties also occur at boundaries between dissimilar materials where the dissimilar materials diffuse across the boundary mixing the dissimilar materials and changing the physical properties. This is especially problematic in via holes when copper or other metallization materials diffuse into the silicon substrate and degrade performance.

A conventional solution to prevent diffusion of dissimilar materials across material boundaries is to apply a diffusion barrier layer over a via hole internal diameter surface and over its base surface to prevent diffusion across the substrate metallization boundary. However since the vias are metalized after the substrate and circuit are interfaced, the barrier layer applied to a bottom surface of the via needs to have relative low resistivity since current flow through the metallized core passes over the barrier layer covering the via hole base surface. Thus one problem with a barrier layer applied to the via hole base surface is that unless the barrier layer has a low resistivity it impedes current flow to the circuit layer. While conventional barrier layers having low resistivity can be formed from nitrides such as titanium nitride (TiN) and tantalum nitride (TaN) cobalt nitride (CoN) such barrier layers are conventionally applied by sputtering. However sputtering fails to provide good performance with high aspect ratio vias since sputtering is unable to coat the via holes to the full depth. In particular sputtering is not adequate beyond an aspect ratio of about 8:1. However one technology that provides full surface coverage even in very high aspect ratio holes is Atomic Layer Deposition (ALD) which is usable to apply TiN and other barrier layer candidates to internal surfaces of high aspect ratio vias.

While conductive TiN barrier layers are known to prevent diffusion across the substrate metallization boundary and provide acceptable current flow across the base surface TiN is not ideally suited to metallization adhesion. More specifically crystal nucleation of copper or other conductive metallization materials on the TiN barrier layer is not acceptable. To improve metallization adhesion to TiN barrier layers it is known to apply noble metals such palladium, platinum, cobalt, nickel and rhodium, among others, over the barrier layer to provided improved copper adhesion and reduce corrosion and oxidization of the barrier layer. However the noble metals are usually applied by Chemical Vapor Deposition (CVD) or Physical Vapor Deposition (PVD) methods which like sputtering provide poor coverage in high aspect ratio vias.

Ma et al. in U.S. Pat. Appl. US2007/0077750A1 entitled ATOMIC LAYER DEPOSITION PROCESSES FOR RUTHENIUM MATERIALS published Apr. 5, 2007 disclose a method of forming a ruthenium material on a dielectric material substrate including silicon dioxide, silicon nitride, silicon oxynitride, carbon-doped silicon oxides or a SiOxCy material substrate as well as forming a Ru layer over a barrier layer material including tantalum, tantalum nitride, tantalum silicon nitride, titanium, titanium nitride, titanium silicon nitride, tungsten, or tungsten nitride) using ALD processes, with a specific example of depositing ruthenium material over tantalum nitride previously formed by an ALD or Physical Vapor Deposition (PVD) process.

However Ma at al. disclose that ruthenocene compounds, such as bis(ethylcyclopentadienyl) ruthenium, bis(cyclopentadienyl) ruthenium, and bis(pentamethylcyclopentadienyl) ruthenium generally deposit a ruthenium material having an increased electrical resistance, poor adhesion (fail the tape test), usually require high adsorption temperatures of above 400° C. and suffer a nucleation delay. As a result Ma at al. conclude that ruthenium precursors containing pyrrolyl ligands are more desirable and that deposition temperatures below 350° C. are more desirable.

Ma et al. further disclose forming a ruthenium material on a substrate by first exposing the substrate to the ruthenium precursors containing pyrrolyl ligands and then exposing the substrate to ammonia plasma, nitrogen plasma, or hydrogen plasma in an ALD system with the plasma generator external or incorporated in the ALD system. In particular Ma et al. seem to recognize that while the ruthenium material can be applied using an oxygen precursor, exposing barrier layers to oxygen is detrimental due to oxidization of the barrier layer.

However in spite of this recognition MA et al. disclose that a seed layer is deposited on the ruthenium material by an initial deposition process and a bulk layer is subsequently deposited thereon by another deposition process. In other words the seed layer taught by MA et al. is applied ex situ by a process other than ALD or PEALD.

### 3. Summary of the Invention

In view of the problems associated with conventional via hole surface coating methods and coated via holes set forth above it is an object of the present invention to prepare a through hole via for metallization by applying an electrically conductive diffusion barrier layer over exposed surfaces of the via by an ALD of PEALD deposition process.

It is a further object to of the present invention to apply an electrically conductive nucleation layer over exposed surfaces of the via diffusion barrier layer by an ALD or PEALD deposition process to nucleate the conductive core material during metallization.

It is a further object of the present invention to protect the barrier layer from oxidization during the application of the nucleation layer by applying a sealing layer over the barrier layer between the barrier layer and the conductive nucleation layer wherein the application of the sealing layer is without oxygen.

The above described shortcomings of the prior art are overcome by the below disclosed electronic device and coating methods.

An electronic device includes through via holes formed by an inside diameter surface bounded by an electrically insulating dielectric layer and a base wall surface bounded by a conductive portion of a circuit layer. The circuit layer is formed integral with the dielectric layer. Each via hole is coated with a titanium nitride (TiN) barrier layer having a thickness ranging from 20 to 200 Å. Each through hole is coated with a ruthenium sealing layer formed over the titanium nitride barrier layer and the sealing layer is formed without oxygen. Each through hole is coated with a ruthenium nucleation layer formed over the ruthenium sealing layer and the ruthenium nucleation layer is formed with oxygen.

The ruthenium sealing layer has a thickness ranging from 5 to 10 Å. The ruthenium nucleation layer has a thickness ranging from 50 to 150 Å. The resistivity of ruthenium nucleation layer is less than the resistivity of the ruthenium sealing layer. Each of the through holes is metalized with copper applied over the ruthenium nucleation layer.

A method for preparing a substrate for metallization includes coating a plurality of through hole vias formed in the substrate such as an electrically insulating dielectric layer. Material layers are applied over an inside diameter surface and a base wall surface of each through hole.

A substrate that includes the through hole vias is positioned inside a process chamber suitable for applying material deposition layers by atomic layer deposition (ALD) and by plasma enhanced atomic layer deposition (PEALD).

A barrier layer comprising a first material is formed over the inside diameter surface and the base wall surface. The first material has a resistivity of less than 300 μohm-cm and is applied with sufficient thickness to substantially prevent diffusion of a metallization material through the barrier layer.

A sealing layer comprising a second material is applied over the entire barrier layer. The second material has a resistivity of less than 300 μohm-cm. Deposition of the sealing layer is carried out substantially without causing oxidation of the first material layer.

A nucleation layer comprising the second material is applied over the entire sealing layer. Deposition of the nucleation layer comprises oxidizing carbon.

During the deposition of each layer the process chamber is at a gas pressure of less than 1 torr and all three of the layers are formed without removing the substrate from the process chamber. The substrate is maintained at a substantially constant temperature between 200 and 400° C. during the formation of all of the layers.

The barrier layer is formed from any of titanium nitride, titanium, tantalum nitride, tantalum, tungsten nitride, cobalt nitride and tungsten and may be formed by either ALD or PEALD. Precursors used to form the titanium nitride barrier layer include tetrakis (dimethylamido) titanium (TDMAT) and nitrogen.

The sealing layer is formed from ruthenium deposited by PEALD without oxygen. The sealing layer is applied using a first precursor comprising a ruthenocene compound and a second precursor comprising plasma excited nitrogen radicals and no oxygen is used.

The nucleation layer is also formed from ruthenium except that the nucleation layer is formed by thermal ALD with oxygen. The nucleation layer is formed using a first precursor comprising a ruthenocene compound and a second precursor comprising non-radicalized oxygen.

After forming the barrier layer, sealing layer and nucleation layer the substrate is removed from the process chamber for ex situ metalizing of the through hole with bulk copper.

These and other aspects and advantages will become apparent when the Description below is read in conjunction with the accompanying Drawings.

### 4. BRIEF DESCRIPTION OF THE DRAWINGS

The features of the present invention will best be understood from a detailed description of the invention and example embodiments thereof selected for the purposes of illustration and shown in the accompanying drawings in which:

FIG. 1 depicts an exemplary schematic diagram of a substrate layer and attached circuit layer showing the structure of through via holes according to the present invention.

FIG. 2 depicts an exemplary schematic diagram of a process chamber and related modules suitable for applying material deposition layers onto via surfaces by thermal atomic layer deposition (ALD) and plasma enhanced atomic layer deposition (PEALD).

### 5. DEFINITIONS

The following definitions are used throughout, unless specifically indicated otherwise:

| TERM | DEFINITION |
|---|---|
| TDMAT | A metal organic species called tetrakis (dimethylamido) |
| | titanium having a chemical formula C8H24N4Ti. Its |
| | properties are strongly influence by the organic ligands |
| | but the compound lacks metal-carbon bonds. |
| ALD | Atomic Layer Deposition or thermal atomic layer |
| | deposition. |
| PEALD | Plasma Enhanced Atomic Layer Deposition wherein at |
| | least one precursor is plasma generated radicals. |
| Ruthenocene | A chemical precursor suitable for forming Ru by ALD |
| compounds, | and PEALD. At least includes bis(ethylcyclopenta- |
| | dienyl) ruthenium, bis(cyclopentadienyl) ruthenium, |
| | and bis(pentamethylcyclopentadienyl) |

### 6. ITEM NUMBER LIST

The following item numbers are used throughout, unless specifically indicated otherwise.

| # | DESCRIPTION |
|---|---|
| 100 | Substrate |
| 105 | 1^{st} circuit layer |
| 110 | Dielectric layer |
| 115 | Through hole via |
| 120 | 1^{st} conductive portion |
| 125 | 2^{nd} circuit layer |
| 130 | 2^{nd} conductive portion |
| 135 | Conductive metal core |
| 150 | Barrier layer |
| 155 | Sealing layer |
| 160 | Nucleation layer |
| 200 | Gas deposition system |
| 205 | Chamber wall |
| 210 | Process chamber |
| 215 | Support chuck |
| 220 | Support surface |
| 225 | Load port |
| 230 | Gate valve |
| 235 | 1^{st} precursor inlet port |
| 240 | 2^{nd} precursor inlet port |
| 245 | Plasma generator |
| 250 | Top aperture |
| 255 | Gas delivery module |
| 260 | Gas supply module |
| 265 | Exit port |
| 270 | Vacuum pump |
| 275 | Exit port module |
| 280 | Electronic controller |
| 285 | Exit valve |
| 290 | Pressure transducer |
| 295 | Temperature sensor |

### 7. EXEMPLARY THROUGH VIA HOLE STRUCTURE

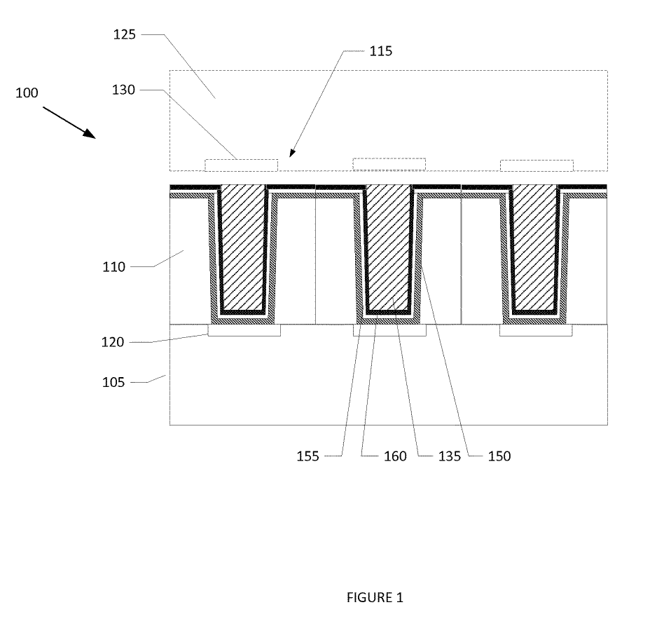

Referring now to FIG. 1, a portion of a multilayer (3-dimensional) integrated circuit (IC) or substrate (100) is shown schematically in side section view according to one non-limiting exemplary embodiment of the present invention. The substrate (100) includes first circuit layer (105) comprising a semiconductor material bulk layer pattered with electrical interconnect patterns and electrical component patterns defined in one or more dielectric material layers and one or more of the interconnect patterns is terminated at an electrically conductive layer or at conductive layer portions (120). The circuit bulk layer comprises semiconductor material, such as, silicon, germanium, gallium arsenide, or the like.

The substrate (100) further includes with an electrically insulating dielectric layer (110) comprising electrically insulating materials such as silicon dioxide, silicon nitride, silicon oxynitride, and/or carbon-doped silicon oxides, such as, SiOₓC_{y} or the like.

A plurality of through hole vias (115) are formed to pass completely through the dielectric layer (110) at locations corresponding to the electrically conductive portions (120). Alternately the electrically conductive portions (120) may extend as a single conductive material layer disposed between the insulating dielectric layer (110) and the semiconductor circuit layer (105).

As will be recognized by those skilled in the art, eventually a second semiconductor circuit layer (125) shown in phantom will be formed or assembled in mating contact with the dielectric layer (110) opposed to the first circuit layer (105) and the second circuit layer will include second conductive portions (130) (or a conductive layer) positioned to make electrical contact with each through hole via (115) opposed to the first conductive pads (120).

Thus each through hole via (115) comprises a through hole formed to extend completely through the electrically insulating dielectric layer (110) such that the first conductive portions (120) are exposed by the formation of each through hole (115). The through hole therefore includes an inside diameter surface bounded by the electrically insulating material of the dielectric layer (110) and a base surface bounded by the electrically conductive material of one of the first conductive portions (120).

The through holes are formed by one or more conventional via hole forming techniques including but not limited to being formed by a wet etch, an electrochemical etch, by laser drilling, and or by ion beam milling or etching such as a deep reactive ion etching (DRIE). Each through hole is eventually filled (metallization) with a conductive material forming a conductive core (135). Example core materials include copper, tungsten, polysilicon, gold, however in the present embodiment copper is preferred. The metal core materials are formable by a conventional electroless and electrochemical plating processes. The conductive material core (135) provides a conductive path extending from one first conductive portion (120) to a corresponding opposing second conductive portion (130). In operation, electrical current passes through conductive material core (135) to provide electrical communication between the first circuit layer (105) and the second circuit layer (125).

A key requirement with via formation is to provide a conductive material core (135) that allows uniform unrestricted current flow over the entire diameter and over the entire length of the core (135). Factors that inhibit current flow or otherwise degrade via performance include void formation in the conductive core (135) and or non-uniform material properties along the length or across diameter of the core, e.g. non-uniform resistivity. A key factor in void formation during metallization is poor adhesion of the conductive core materials to the inside diameter surface and base wall surface of the through hole. This problem is solved by the present invention by providing a nucleation or seed layer (160) [solid black] in mating contact with the core (135) at both the inside diameter surface and the base wall surface of the via hole (115). The nucleation layer (160) is configured to initiate crystallization of metallic conductors used to metallize the core. The presence of the nucleation layer (160) improves adhesion of the material of metal core (135) to the inside diameter and base wall surfaces of the through hole and this reduces void formation at boundary edges of the core (135). In particular the present invention forms the nucleation layer by an in-situ Atomic Layer Deposition process.

A key factor in generating non-uniform material properties in and around the core (135) is diffusion of the conductive core material into the electrically insulating dielectric material of the dielectric layer (110) during metallization. This problem is solved by the present invention by providing a diffusion barrier layer (150) [solid grey] inside the via hole over the through hole inside diameter surface and base wall surface wherein the diffusion barrier layer (150) is deposited by ALD or PEALD. The diffusion layer (150) is formed with sufficient material thickness to substantially prevent dissimilar materials, especially copper, from crossing the diffusion layer (150). The diffusion layer (150) is formed from a material having a resistivity of less than about 300 ohm-cm in order to minimally impede electrical current flow through the base surface of the diffusion layer (150) at the electrical interface between the conductive core (135) and the first conductive portion (120). Preferably the diffusion layer (150) is formed from a material that can be applied by a thermal ALD process or a PEALD process at reaction temperatures of less than 500° C. and preferably within a reaction temperature range of 250 to 350°.

According to one non-limiting exemplary aspect of the present invention the through hole vias (115) are formed as follows. Each through hole is formed by a suitable hole forming technique described above. While different through hole vias (115) may have the same or different hole diameters, the diameter of any given through hole preferably ranges between 12 and 30 μm but larger diameter through holes can be processed by the present invention. The depth or length of each through hole (115) is substantially equal to a thickness of the dielectric layer (110) which in the present non-limiting example embodiments is between 200 and 600 μm for high aspect ratio vias but shorter length through holes can be processed by the present invention. A center to center pitch dimension between through holes (115) is 50 μm or above but smaller center pitch dimension through holes can be processed by the present invention. Accordingly the present invention is suitable for very high aspect ratio vias with a hole diameter to hole depth aspect ratio ranging up to 50 or higher if higher aspect ratio via holes can be formed.

Each via hole (115) includes a diffusion barrier layer (150) applied directly onto inside surfaces of the via hole including on the inside diameter surface formed by the dielectric layer (110) and on the through hole base surface formed by the conductive portion (120). The barrier layer (150) is formed to prevent or substantially minimize diffusion of metal metallization materials, preferably copper, across the barrier layer (150) during core metallization. The barrier layer (150) comprises a material having low enough resistivity to provide substantially unimpeded current flow across the base surface of the diffusion layer. In one non-limiting example embodiment the barrier layer (150) comprises titanium nitride (TiN) applied to a layer thickness in the range of 20 to 200 Å, (2 to 20 nm). The TiN barrier layer (150) is applied by either of a thermal Atomic Layer Deposition (ALD) process or a plasma enhanced atomic layer deposition (PEALD) process. Alternately the barrier layer (150) comprises one of TiN applied to a layer thickness in the range of 20 to 200 Å, (2 to 20 nm) by a Plasma Enhanced Atomic Layer Deposition (PEALD) process. Other example barrier layer materials suitable for the present invention include titanium, tantalum nitride, tantalum, tungsten nitride, and tungsten formed by an ALD or a PEALD process. In each case the resistivity of the barrier layer is below 300 ohm-cm and preferably

Each via hole (115) includes a sealing layer (155) [white area] applied directly over the diffusion barrier layer (150) between the barrier layer (150) and a nucleation layer (160) detailed below. The sealing layer (155) is applied over the inside diameter surface and the base wall surface of the barrier layer (150) in the through hole (115) and comprises a material having low enough resistivity, e.g. having a resistivity of less than 300 ohm-cm, to allow substantially unimpeded current flow across the base wall surface. The sealing layer (155) is formed without oxygen and is specifically applied over the barrier layer to prevent oxidation of the barrier layer material during application of the nucleation layer (160) which as will be described below is deposited with oxygen. Oxidation of the barrier layer tends to increase the resistivity of the barrier layer which in turn impedes current flow through the barrier layer (150) across the base surface.

The sealing layer (155) comprises ruthenium (Ru) applied with a sufficient layer thickness to prevent oxygen from reacting with surfaces of the barrier layer during application of the nucleation layer (160). In the present non-limiting example embodiment a sealing layer (155) comprising Ru is applied with a layer thickness ranging from 5 to 10 Å, (0.5 to 1.0 nm) wherein application of the sealing layer is performed without exposing the barrier layer material to oxygen. The sealing layer (155) is formed by a PEALD process using a first ruthenium precursor comprising a ruthenocene compound such as one or more of bis(ethylcyclopentadienyl) ruthenium, bis(cyclopentadienyl) ruthenium, and bis(pentamethylcyclopentadienyl) ruthenium. Thereafter a second precursor comprising a plasma excited nitrogen radical is introduced into the process chamber to complete a single monolayer of Ru and the second precursor is generated from any one of plasma excited N₂ gas, ammonia (NH₃), and hydrazine or combinations thereof.

Each via hole (115) includes a nucleation layer (160) applied directly over the sealing layer (155) on the inside diameter surface and the base wall surface of the barrier layer (150) in the through holes (115). The nucleation layer (160) comprises a material have low enough resistivity to provide substantially unimpeded current flow across the base surface of the nucleation layer, e.g. less than 300 ohm-cm. The nucleation layer (160) is disposed between the conductive core (135) and the sealing layer (155) and is specifically provided to nucleate crystal growth of the material of the conductive core during metallization. In the present non-limiting example embodiment the material of the nucleation layer is Ru applied by a thermal ALD process that includes oxidizing carbon. The nucleation layer is applied to a thickness in the range of 50 to 150 Å (5-15 nm). While the sealing layer (155) and the nucleation layer (160) are both Ru layers, the resistivity of the nucleation layer is less than the resistivity of the sealing layer due to the different deposition processes. The lower resistivity in the nucleation layer (160) occurs in part because the ruthenium precursor ligands are more highly reactive to oxygen than to nitrogen. As a result the nucleation layer (160) formed with oxygen is formed with reduced impurities and a corresponding reduced resistivity as compared with the sealing layer (155) formed with nitrogen. The impurity reduction in the nucleation layer further improves copper nucleation during metallization.

While Ru is the preferred material for forming the seed layer and the nucleation layer from different chemistries other material candidates are usable without deviating from the present invention and these include but are not limited to palladium (Pd), platinum (Pt), rhodium (Rh), iridium (Ir), silver (Ag), cobalt (Co), molybdenum (Mo), chromium (Cr), and tungsten (W).

Each via hole (115) includes a conductive metal core (135). In the present non-limiting example embodiment the metal core (135) comprises bulk copper and the bulk copper core (135) is formed by a conventional electroless deposition process using a redox reaction, a physical deposition process, an electron beam evaporation process, an electrochemical plating (ECP) process, a chemical vapor deposition (CVD) process, or the like; preformed ex-situ. Additionally other conductive core material such as tungsten, polysilicon, and gold are usable without deviating from the present invention.

More specifically each of the barrier layer (150), the sealing layer (155) and the nucleation layer (160) is formed in the same ALD process chamber without removing the substrate (100) from the ALD process chamber. Moreover the ALD process chamber includes a plasma generator and is configured to carry out material deposition cycles by thermal ALD and or by PEALD. After the application of the barrier layer, the sealing layer and the nucleation layer is complete, the substrate (100) is removed from the ALD process chamber to an another station for metallization of the core with copper. Other core metallization materials are also usable.

According to a further aspect of the present invention the barrier layer (150), the sealing layer (155) and the nucleation layer (160) are applied by different Atomic Layer Deposition (ALD) and Plasma Enhanced Atomic Layer Deposition (PEALD) processes. More specifically the titanium nitride barrier layer (150) is formed on all of the through hole vias simultaneously by a first ALD coating sequence, the ruthenium sealing layer (155) is formed over the barrier layer (150) of all the through hole vias simultaneously by a second PEALD coating sequence carried out without exposing the barrier layer to oxygen and the nucleation layer (160) is formed over the sealing layer (150) of all the through hole vias simultaneously by a third ALD coating sequence that includes oxidizing carbon.

### 8. EXEMPLARY GAS DEPOSITION SYSTEM AND OPERATING MODES

According to the present invention the substrate (100) comprising the electrically insulating dielectric layer (110) and the attached circuit layer (105) are prefabricated by conventional circuit fabrication techniques that are well known. In one non-limiting example embodiment the dialectic layer (110) comprises an electrically insulating dielectric material such as silicon dioxide, silicon nitride, silicon oxynitride, and/or carbon-doped silicon oxides, such as, SiOₓC_{y} or the like. The substrate (100) may comprise a disk shaped wafer with a diameter of one of 25, 50, 100, 200, or 300 mm. However, dielectric layer (110) may have other shapes and be formed from other materials without deviating from the present invention.

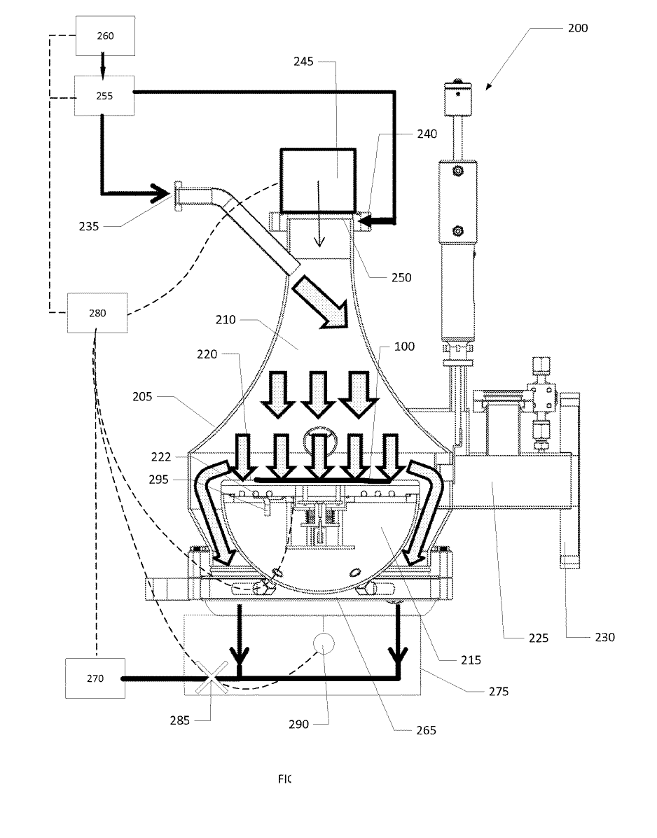

Referring now to FIG. 2 a side section view of a non-limiting exemplary gas deposition system (200) is shown schematically. The system (200) comprises an outer chamber wall (205) enclosing a process chamber (210). A support chuck (215) disposed inside the process chamber (210) provides a support surface (220) for supporting a substrate (100) thereon during gas deposition coating cycles. The support chuck (215) may further include an electrical resistance heating elements (222) disposed below the support surface (220) operable to heat the substrate (100) supported on the support surface (220) to a desired reaction temperature as may be required by the particular gas deposition coating materials and gas deposition processes being carried out.

The system (200) includes a load port (225) having a port gate valve (230) usable to pass a substrate (100) to be gas deposition coated through the outer chamber wall (205) in order to rest one or more substrates (100) to be deposition coated onto the support surface (220). The loading and unloading of each substrate can be done manually, e.g. using wafer tweezers or the like, to pass substrates to be deposition coated through the port gate valve (230) and load port (225). Alternately an automated wafer loading and unloading device, not shown, may be used in combined with the deposition system (200) and operable to automatically load substrates at the beginning of a gas deposition coating cycle and to automatically remove substrates at the end of gas deposition coating cycle. In particular an automated loading and unloading system advantageously allows the loading and unloading of substrates without breaking vacuum thereby reducing pump down times between deposition cycles.

The system (200) comprises a non-plasma precursor inlet port (235) passing directly through the outer wall (205) for delivering a first and or a second precursor directly into to the process chamber (210) without plasma excitation. The system (200) comprises a plasma precursor inlet port (240) passing through an outer wall of a plasma generator module (245) for delivering a first or second precursor into the plasma generator module (245) for plasma excitation. Precursors delivered into the plasma generator module (245) enter the process chamber (210) through a top aperture (250).

Each of the precursor inlet ports is in fluid communication with a process gas delivery module (255) and associated process gas supply module (260). The process gas supply module (260) houses containers filled with various process materials which may include containers filled with liquid, solid and gaseous state process materials. The process gas delivery module (255) includes one or more bubblers, or the like, not shown, for generating vaporous precursor supplies, e.g. extracted from solid or liquid precursor source materials, and various flow control elements including pulse valves, not shown, for delivering pulses of precursor vapor to appropriate precursor ports (235) and (240) wherein each precursor pulse has a desired pulse volume which provides a quantity of precursor vapor that is suitable for the particular ALD or PEALD coating process being carried out.

Additionally the process gas supply module (260) includes or is connected to an inert gas supply and the gas delivery module (255) is configured to deliver inert gas to each of the precursor ports (235) and (240). The inert gas flow is modulated by the gas delivery module (255) which is operable to control the pressure and flow rate of inert gas as required to deliver a continuous flow of inert gas through each precursor port or to modulate inert gas flow to deliver intermittent inert gas flow into the process chamber (210) through either or both of the precursor inlet ports (235) and (240). In any case the inert gas flow may be used as a carrier gas for carrying precursor vapor to the process chamber (210). Additionally only an inert gas is flowed through the process chamber to flush or purge the process chamber (210) between precursor cycles.

The PEALD system (200) comprises an exit port (265) in fluid communication with a vacuum pump (270) and the vacuum pump (270) operates to evacuate the process chamber (210) by removing gases from the process chamber through the exit port (265). The gases removed from the process chamber include any unreacted precursor material and or any reaction byproducts of a deposition coating cycle. Additionally an exit port module (275) includes a pressure gage (290), or the like, to provide local gas pressure readings to an electronic controller (280) and a vacuum valve module (285) operably by the electronic controller (280) to seal a conduit leading the vacuum pump. Additionally one or more temperature sensors (295) are provided to monitor local temperature and report temperature information to the electronic controller (280).

In operation the system (200) is usable to apply thin film material coatings onto the substrate (100) described above. The substrate (100) is supported on the support chuck (215) with the first circuit layer (105) in contact with the support surface (220) and the dielectric layer (110) facing upward toward the top aperture (250). Process gas entering the chamber (210) through the precursor port (235) and top aperture (250) expands to fill the chamber (210) and impinges a top surface of the dielectric layer (110) and some process gas enters into the via holes (115) to react with surfaces thereof. The process gases react with any exposed surfaces of the substrate (100) and form thin film deposition layers on all of the exposed surfaces which at least include the top surface of the substrate layer (110) and the inside wall surfaces of the via holes (115) including the base surface formed by the first conductive portions (120).

As is well known, each ALD coating cycle is based on two self-limiting reactions. A first self-limiting reaction between a first precursor and exposed surfaces of a substrate creates a first half monolayer of solid material onto the exposed surfaces of the substrate and a second self-limiting reaction between a second precursor and exposed surfaces of the substrate creates a second half monolayer of the solid material onto the exposed surfaces of the substrate. More specifically two separate and independent self-limiting precursor reactions with the exposed surfaces are performed to deposit a single monolayer of a desired material onto the exposed surfaces. Moreover due to the self-limiting nature of the reaction the thickness of the single material monolayer is substantially predetermined and approximately equal to a single atomic layer of the material, e.g. each monolayer has an approximate thickness of 0.5 to 1.5 Å depending on various growth conditions at least including temperature, precursor vapor pressure and volume, gas pressure inside the process chamber and exposure time. Since in most applications at least 5 monolayer applications are required to provide a minimal functional material coating thickness the two self-limiting reactions are repeated 5 times to deposit 5 monolayers of the coating material being deposited. More generally however, ALD coating thicknesses of 100 to 200 monolayers and in some cases up to about 1000 monolayers are used to coat substrates with the desired surface coating in order to take advantage of whatever material property the surface coating is providing.

The system (200) is configured for automated coating cycle operation based on operating mode menus, or the like, stored in the electronic controller (280) and selectable or programmable by a user. In one non-limiting example a user may enter or select a process type (e.g. ALD, PEALD), and select chemistries, e.g. a first precursor, a second precursor, a reaction temperature and a desired number of monolayers. Additionally inert gas flow and modulation parameters may be user selectable as well as exposure time which for long exposure times may include closing the vacuum exit valve (285) during a deposition cycle. Once the coating cycle parameters are selected the system (200) performs the selected coating sequence by automatically applying monolayers until the desired surface coating is completely formed to the desired number of monolayers. Thereafter the user may remove the substrate, install another substrate and repeat the same coating cycle for a new substrate or may perform other coating cycles to add additional deposition coating layer to the same substrate.

Alternately the user may enter a sequence of coating cycles wherein a first material is coated onto exposed surfaces to a desired thickness or number of monolayer cycles and thereafter a second material is coated onto exposed surfaces, over the first material layer to a desired thickness or number of monolayer cycles and so on to apply additional material coatings. In this example application the user enters two or more coating formulas with each formula specifying a different process type, (if applicable), a different chemistry or first and second precursor combination, (if applicable), a different reaction temperature, (if applicable), and a different desired thickness or number of monolayers (if applicable) for each of the two or more coating materials. Once the coating cycle parameters for two or more coating cycles are selected and entered the system (200) performs the first coating sequence automatically until the first surface coating is completely formed to the desired number of monolayers. Thereafter the system (200) automatically performs the second coating sequence using different parameters until the second surface coating is completely formed to the desired number of monolayers. Thereafter the system (200) automatically performs a third coating sequence using different parameters until the third surface coating is completely formed to the desired number of monolayers.

Thereafter the user may remove the substrate, install another substrate and repeat the same two or more coating cycles for a new substrate.

An example gas deposition system (200) usable to apply three or more material coating layers onto internal surfaces of via holes according to the present invention is described in related published U.S. Pat. Appl. 2010/018325A1 entitled PLASMA ATOMIC LAYER DEPOSITION SYSTEM AND METHOD filed on Dec. 28, 2009 by Becker et al. which is incorporated herein by reference in its entirety.

### 9. EXEMPLARY COATING PROCESS FOR FORMING THE BARRIER LAYER

In one non-limiting example embodiment of the present invention via hole internal surfaces are coated with a barrier layer (150) comprising Titanium Nitride (TiN). The barrier layer (150) is applied to a layer thickness ranging from 20 to 200 Å using the above described system (200) as follows.
The substrate (100) is inserted into the process chamber (210) through the gate valve (230) and inlet port (225) and placed on the support surface (220) with a top surface of the dielectric layer (110) facing the top aperture (250), i.e. with the open end of the via holes facing the top aperture (250). In the present example the substrate (100) is a 100, 200 or 300 mm wafer and each wafer is processed one at a time. However a plurality of substrates (100) can be processed in one batch without deviating from the present invention.
The gate valve (230) is closed, either automatically or by a user. The system (200) operates to heat the substrate (100) to a desired reaction temperature and the vacuum pump (270) runs continuously to evacuate the chamber to achieve a desired reaction pressure. In the present example the preferred reaction or substrate temperature for deposition of the TiN barrier layer is between 270° C. and 400° C. and the desired reaction pressure is between 1 and 100 μtorr (1.33-133.32 mPa). However other reaction temperatures for TiN, e.g. ranging from 200-500° C., and other reaction pressures, e.g. ranging from 1 to 10,000 μtorr are usable without deviating from the present invention.
The chamber is purged by a continuous or intermittent flow of inter gas passed into the chamber through one or both of the precursor inlet ports (235) and (240) or through another port, not shown, to remove moisture and other contaminates.
A first thermal ALD coating cycle is initiated to apply the TiN barrier layer onto exposed surfaces of the substrate (100).
A first metal organic precursor comprising tetrakis (dimethylamido) titanium (TDMAT) is introduced into the process chamber through the first precursor port (235). The first precursor is introduced as a vapor pulse generated by operating a pulse valve, not shown, for a pulse duration wherein the pulse duration is proportional to a volume of first precursor vapor contained in the vapor pulse. The first precursor pulse may be mixed with a continuous flow of inert gas flowing from the process gas delivery module (255) to the first precursor port (235).
(1) The first precursor is allowed to react with the exposed surfaces of the substrate (100) for duration equal to a predefined exposure time. The exposure time may be a function of the system design. For example the exposure time of a precursor pulse to the substrate may be substantially equal to the time it takes for the vacuum pump (270) to draw a volume of gas equal to the total volume of the process chamber (210) plus the additional volume of gas conduits leading into the process chamber through the exit port (265). In this case the exposure time may be on the order of 10-2000 msec. For much longer exposure times e.g. up to about 60 seconds the vacuum valve (285) may be closed to prevent precursor from exiting the process chamber for a desired exposure time duration.
Preferably the duration of each precursor pulse (time that the pulse valve is opened for) is optimized in order to provide sufficient precursor vapor volume in a single pulse to substantially saturate or fully react with exposed surfaces of the substrate being coated. In other words each precursor pulse includes enough precursors to complete the above described self-limiting reaction with exposed surfaces in the time it takes for the precursor pulse to pass through the process chamber (210).
(2) A first purge cycle is performed wherein the process chamber (210) is purged to remove all traces of the first precursor. This may involve simply allowing the vacuum pump and continuous inert gas flow to flush the chamber to remove a gas volume equal to 2-5 times the volume of the process chamber (210) and flow conduits leading to the chamber.
(3) A second precursor comprising nitrogen is introduced into the process chamber through the first precursor port (235). The second precursor such as ammonia (NH₃) is introduced as a vapor pulse generated by operating a pulse valve, not shown, for a pulse duration wherein the pulse duration is proportional to a volume of second precursor vapor contained in the vapor pulse. The second precursor pulse may be mixed with a continuous flow of inert gas flowing from the process gas delivery module to the first precursor port (235).
The second precursor is allowed to react with the exposed surfaces of the substrate (100) for a duration equal to a predefined exposure time.
(4) A second purge cycle is performed wherein the process chamber (210) is purged to remove all traces of the second precursor.
The above described 4 step cycle is one example of a thermal ALD deposition process usable to generate a single monolayer of the barrier layer (150) wherein the barrier layer comprises TiN. The 4 step process is repeated to apply additional monolayers until a desired barrier layer thickness is achieved.

In an alternate embodiment of applying the barrier layer (150) of the present invention, TiN can be applied by PEALD. While the same 4 step process is performed, the second precursor is replaced by plasma excited nitrogen radicals delivered from the plasma generator (245) into the process chamber (210) through the top aperture (250). The plasma radicals are derived from a second precursor delivered from the process gas delivery module (255) into plasma generator (245) through the second precursor port (240). In particular a second precursor may comprise any one of nitrogen gas (N₂) a mixture of nitrogen and hydrogen gas or ammonia. In all other aspects the above described process for forming the barrier layer is substantially the same.

In any of the above examples the precursors are preheated to about 75° C. to achieve the desired vapor pressure for pulsing. The minimum barrier layer thickness (about 20 Å) is achieved by preforming about 34-40 monolayer applications wherein each monolayer has a thickness of about 0.5 to 0.6 Å. The maximum barrier layer thickness (about 200 Å) is achieved by preforming about 333-400 monolayer applications.

### 10. EXEMPLARY COATING PROCESS FOR FORMING THE SEALING LAYER (WITHOUT OXYGEN)

In one non-limiting example embodiment of the present invention via hole internal surfaces are coated with a sealing layer (155) comprising ruthenium (Ru). The sealing layer (155) is applied to a layer thickness ranging from 5 to 10 Å using the above described system (200) as follows. The substrate temperature may be changed to a temperature in the range of 250 to 350° C. to apply the sealing layer (155). However in a preferred method the same deposition temperature of about 300° C. is used to deposit the barrier layer, the sealing layer and the nucleation layer.
(1) A first precursor comprising a ruthenocene compound is introduced into the process chamber through the first precursor port (235). The ruthenocene compounds, include but are not limited to bis(ethylcyclopentadienyl) ruthenium, bis(cyclopentadienyl) ruthenium, and bis(pentamethylcyclopentadienyl) ruthenium. In particular the chemical compound of bis(ethylcyclopentadienyl) ruthenium=(EtCp)2Ru=Ru(C5H4C2H5)2 of bis(cyclopentadienyl) ruthenium=Cp2Ru=Ru(C5H5)2 and of bis(pentamethylcyclopentadienyl) ruthenium=(Me5Cp)2Ru=Ru(C5(CH3)5)2
The first precursor is introduced as a vapor pulse generated by operating a pulse valve, not shown, for a pulse duration wherein the pulse duration is proportional to a volume of first precursor vapor contained in the vapor pulse. The first precursor pulse may be mixed with a continuous flow of inert gas flowing from the process gas delivery module to the first precursor port (235). The ruthenocene compound pulse reacts with surfaces of the barrier layer (150) to form a first half mono layer of the sealing layer (155).
(2) A first purge cycle is performed wherein the process chamber (210) is purged to remove all traces of the first precursor.
(3) A second precursor comprising a mixture of nitrogen and hydrogen gases is flowed into the plasma generator (245) through the second precursor port (240). The plasma generator is ignited to excite the nitrogen and hydrogen which react with the exposed surfaces of the substrate to complete the formation of a first monolayer of Ru. The hydrogen gas is included to break down the first Ru half monolayer layer deposited over the TiN barrier layer by the first precursor however the present coating step can be performed without hydrogen without deviating from the present invention. The completed monolayer has a thickness of about 0.5 Å and is formed without oxygen to avoid oxidation of the barrier layer (150). The second precursor may comprise any one of N₂ gas, ammonia and hydrazine which are excited by a plasma source.
(4) A second purge cycle is performed wherein the process chamber (210) is purged to remove all traces of the second precursor.

The above described 4 step cycle is one example of a PEALD deposition process usable to generate a single monolayer of the sealing layer (155) wherein the sealing layer comprises Ru formed by a ruthenocene compound without oxygen. The 4 step process is repeated to apply additional monolayers of Ru until a desired sealing layer thickness is achieved. The minimum sealing layer thickness (about 5 Å) is achieved by preforming about 10 monolayer applications wherein each monolayer has a thickness of about 0.5 Å. The maximum sealing layer thickness (about 10 Å) is achieved by preforming about 20 monolayer applications. A thicker sealing layer application is usable without deviating from the present invention.

### 11. EXEMPLARY COATING PROCESS FOR FORMING THE NUCLEATION LAYER (WITH OXYGEN)

In one non-limiting example embodiment of the present invention via hole internal surfaces already coated with the barrier layer (150) and the sealing layer (155) are coated with a nucleation layer (160) comprising ruthenium (Ru). The nucleation layer (160) is applied over the Ru sealing layer (155) with a layer thickness ranging from 50 to 150 Å using the above described system (200) as follows. The substrate temperature may be changed to a temperature in the range of 250 to 350° C. to apply the nucleation layer (160). However a preferred method performs the deposition of the barrier layer, the sealing layer and the nucleation layer with the substrate maintained at the same temperature e.g. 300° C.
(1) A first precursor comprising a ruthenocene compound is introduced into the process chamber through the first precursor port (235). The first precursor is introduced as a vapor pulse generated by operating a pulse valve, not shown, for a pulse duration wherein the pulse duration is proportional to a volume of first precursor vapor contained in the vapor pulse. The first precursor pulse may be mixed with a continuous flow of inert gas flowing from the process gas delivery module to the first precursor port (235). The ruthenocene compound pulse reacts with surfaces of the sealing layer (155) to form a first half mono layer of Ru of the nucleation layer (160).
(2) A first purge cycle is performed wherein the process chamber (210) is purged to remove all traces of the first precursor.
(3) A second precursor comprising oxygen is introduced into the process chamber through the first precursor port (235). The second precursor is introduced as a vapor pulse generated by operating a pulse valve, not shown, for a pulse duration wherein the pulse duration is proportional to a volume of second precursor vapor contained in the vapor pulse. The second precursor pulse may be mixed with a continuous flow of inert gas flowing from the process gas delivery module to the first precursor port (235). The oxygen reacts with surfaces of the first monolayer formed by the first precursor to complete the formation of a first half mono layer of Ru generated with oxygen. The oxygen precursor is usable without oxidizing the TiN barrier layer because the sealing layer (155) prevents oxygen from reaching the barrier layer (150). Moreover the oxygen oxidizes carbon during the formation of the nucleation layer which supports copper crystal nucleation and adhesion to the nucleation layer (160) during metallization of the conductive metal core (135). The reaction is characterized as follow:
   O2 pulse: O2->O (adsorbed)
   Ru precursor pulse: Ru(C5H4C2H5)2 (adsorbed)+O (adsorbed)->Ru+CO2+H2O
(4) A second purge cycle is performed wherein the process chamber (210) is purged to remove all traces of the second precursor.

The above described 4 step cycle is one example of a thermal ALD deposition process usable to generate a single monolayer of a Ru nucleation layer (160) wherein the nucleation layer comprises Ru formed with oxygen. The 4 step process is repeated to apply additional monolayers until a desired nucleation layer thickness is achieved. The minimum nucleation layer thickness (about 50 Å) is achieved by preforming about 100 monolayer applications wherein each monolayer has a thickness of about 0.5 Å. The maximum nucleation layer thickness (about 150 Å) is achieved by preforming about 300 monolayer applications. A thicker nucleation layer application is usable without deviating from the present invention.

More generally ruthenocene compounds containing metallocenes such as bis(ethylcyclopentadienyl) ruthenium, bis(cyclopentadienyl) ruthenium, and bis(pentamethylcyclopentadienyl) ruthenium are preferred for the sealing layer and nucleation layer formation. However other ruthenium precursors are usable including a pyrrolyl ruthenium precursor containing ruthenium and at least one pyrrolyl ligand. Such materials can be derived from methylcyclopentadienyl pyrrolyl ruthenium ((MeCp)(Py)Ru).

It will also be recognized by those skilled in the art that, while the invention has been described above in terms of preferred embodiments, it is not limited thereto. Various features and aspects of the above described invention may be used individually or jointly. Further, although the invention has been described in the context of its implementation in a particular environment, and for particular applications (e.g. applying deposition coatings to inside surfaces of through hole vias), those skilled in the art will recognize that its usefulness is not limited thereto and that the present invention can be beneficially utilized in any number of environments and implementations where it is desirable to form deposition layers in a manner that improves IC performance. Accordingly, the claims set forth below should be construed in view of the full breadth and spirit of the invention as disclosed herein.

1. An electronic device comprising through via holes formed by an inside diameter surface and a base wall surface wherein all surfaces are coated with:
a titanium nitride barrier layer having a thickness ranging from 20 to 200 Å;
a metallic ruthenium sealing layer formed over the titanium nitride barrier layer wherein the metallic ruthenium sealing layer is formed without exposing the titanium nitride barrier layer to oxygen; and
a metallic ruthenium nucleation layer formed over the metallic ruthenium sealing layer wherein the metallic ruthenium nucleation layer is formed with oxygen.

2. The electronic device of claim 1 wherein the metallic ruthenium sealing layer has a thickness ranging from 5 to 10 Å.

3. The electronic device of claim 2 wherein the metallic ruthenium nucleation layer has a thickness ranging from 50 to 150 Å.

4. The electronic device of claim 3 wherein the resistivity of metallic ruthenium nucleation layer is less than the resistivity of the metallic ruthenium sealing layer.

5. The electronic device of claim 4 wherein the through via hole is metalized with copper by applying the copper over the metallic ruthenium nucleation layer.

6. An integrated electrical device assembly comprising:
a dielectric substrate layer comprising an electrically insulating material;
a circuit layer supported on the dielectric substrate layer comprising a semiconductor material layer pattered with electrical device and interconnect patterns;
a conductive layer disposed between the dielectric substrate layer and the circuit layer at least including conductive layer portions in electrical communication with at least one of the interconnect patterns;
a through hole via passing completely through the dielectric substrate layer to the conductive layer comprising an inside diameter surface bounded by the dielectric substrate layer and a base wall surface bounded by one of the conductive layer portions;
a titanium nitride barrier layer formed over each of the inside diameter surface and the base wall surface comprising a first material having a resistivity of less than 300 μohm-cm wherein the titanium nitride barrier layer is formed with sufficient layer thickness to prevent diffusion of a via hole metallization material there through;
a metallic ruthenium sealing layer formed over the titanium nitride barrier layer over each of the inside diameter surface and the base wall surface comprising a second material having a resistivity of less than 300 μohm-cm wherein formation of the metallic ruthenium sealing layer is carried out without exposing the first material to oxygen;
a metallic ruthenium nucleation layer formed over the metallic ruthenium sealing layer over each of the inside diameter surface and the base wall surface comprising the second material wherein formation of the metallic ruthenium nucleation layer comprises oxidizing carbon.

7. The integrated electrical device assembly of claim 6 wherein the first material comprises any one of titanium nitride, titanium, tantalum nitride, tantalum, tungsten nitride, cobalt nitride and tungsten.

8. The integrated electrical device assembly of claim 7 wherein the titanium nitride barrier layer thickness is between 19 and 201 Å.

9. The integrated electrical device assembly of claim 7 wherein the second material comprises metallic ruthenium.

10. The integrated electrical device assembly of claim 9 wherein the metallic ruthenium sealing layer thickness is between 4 and 11 Å and the metallic ruthenium nucleation layer thickness is between 49 Å to 151 Å.

11. The integrated electrical device assembly of claim 9 wherein deposition of the metallic ruthenium sealing layer over the titanium nitride barrier layer includes forming a plurality of metallic ruthenium monolayers over exposed surfaces of the through hole via wherein each of the plurality of metallic ruthenium monolayers is formed by reacting a ruthenocene compound with the exposed surfaces of the through hole via followed by reacting plasma generated nitrogen radicals with the exposed surfaces of the through hole via.

12. The integrated electrical device assembly of claim 6 wherein the through hole via has a diameter of less than 30 μm with a through hole depth of more than 200 μm.

13. The integrated electrical device assembly of claim 6 wherein the metallization material comprises bulk copper.

14. A method for preparing a through hole via for metallization wherein the through hole via comprises an inside diameter surface and a base wall surface comprising:
positioning a substrate that includes at least one through hole via inside a process chamber suitable for applying material deposition layers by atomic layer deposition (ALD) and by plasma enhanced atomic layer deposition (PEALD);
depositing by ALD or PEALD a barrier layer comprising a first material over each of the inside diameter surface and the base wall surface of the at least one through hole via wherein the first material has a resistivity of less than 300 μohm-cm and is applied with sufficient thickness to prevent diffusion of a metallization material through the barrier layer;
depositing by ALD or PEALD a metallic ruthenium sealing layer comprising a second material over the entire barrier layer wherein the second material has a resistivity of less than 300 μohm-cm and deposition of the metallic ruthenium sealing layer is carried out without exposing the first material to oxygen; and,
depositing by ALD or PEALD a metallic ruthenium nucleation layer comprising the second material over the entire metallic ruthenium sealing layer and wherein the deposition of the metallic ruthenium nucleation layer comprises oxidizing carbon.

15. The method of claim 14 further comprising:
maintaining the process chamber at a gas pressure of less than 1 torr during the deposition of each of the barrier layer, the metallic ruthenium sealing layer, and the metallic ruthenium nucleation layer; and,
depositing each of the barrier layer, the metallic ruthenium sealing layer, and the metallic ruthenium nucleation layer without removing the substrate from the process chamber.

16. The method of claim 15 further comprising maintaining the substrate at a constant temperature during the deposition of each of the barrier layer, the metallic sealing ruthenium layer, and the metallic ruthenium nucleation layer.

17. The method of claim 16 wherein the constant temperature is a temperature between 199 and 40° C.

18. The method of claim 17 further comprising maintaining the substrate at at least two different constant temperatures during the deposition of at least two of the barrier layer, the metallic ruthenium sealing layer, and the metallic ruthenium nucleation layer.

19. The method of claim 18 wherein each of the at least two different constant temperatures are temperatures between 199 to 501° C.

20. The method of claim 14 wherein depositing the barrier layer from any one of titanium nitride, titanium, tantalum nitride, tantalum, tungsten nitride, cobalt nitride and tungsten.

21. The method of claim 20 further comprising depositing the barrier layer by thermal atomic layer deposition.

22. The method of claim 20 further comprising depositing the barrier layer by plasma enhanced atomic layer deposition.

23. The method of claim 14 wherein the first material comprises titanium nitride and the method further comprising the steps of depositing the barrier layer by:
exposing the inside diameter surface and the base wall surface of each of the at least one through hole via to a first precursor comprising tetrakis (dimethylamido) titanium (TDMAT) for an exposure time sufficient to complete a self-limiting reaction of the TDMAT with the inside diameter and base wall surfaces;
purging the TDMAT and reaction byproducts from the process chamber;
exposing the inside diameter surface and the base wall surface of each of the at least one through hole via to a second precursor comprising nitrogen for an exposure time sufficient to complete a self-limiting reaction of the nitrogen with the inside diameter and base wall surfaces;
purging the nitrogen and reaction byproducts from the process chamber;
repeating the above exposing and purging steps until the first material thickness is between 19 to 201 Å.

24. The method of claim 23 wherein depositing the barrier layer is performed by a thermal atomic layer deposition process wherein the second precursor comprises ammonia (NH₃).

25. The method of claim 23 wherein depositing the barrier layer is performed by a plasma enhanced atomic layer deposition process wherein the second precursor comprises plasma excited nitrogen radicals.

26. The method of claim 14 wherein the second material comprises metallic ruthenium.

27. The method of claim 26 further comprising depositing the metallic ruthenium sealing layer over the barrier layer by:
exposing the inside diameter surface and the base wall surface of the at least one through hole via to a first precursor comprising a ruthenocene compound for an exposure time sufficient to complete a self-limiting reaction of the ruthenocene compound with the inside diameter and base wall surfaces;
purging the ruthenocene compound from the process chamber;
exposing the inside diameter and the base wall of the at least one through hole via to a second precursor comprising plasma generated nitrogen radicals and no oxygen;
purging the nitrogen radicals and reaction byproduct from the process chamber; and
repeating the above exposing and purging steps until the metallic ruthenium sealing layer thickness is at least 4 Å.

28. The method of claim 27 further comprising the steps of depositing the metallic ruthenium nucleation layer over the metallic ruthenium sealing layer by:
exposing the inside diameter surface and the base wall surface of the at least one through hole via to a first precursor comprising a ruthenocene compound;
purging the ruthenocene compound and reaction byproducts from the process chamber;
exposing the inside diameter surface and the base wall surface of the at least one through hole via to a second precursor comprising non-radicalized oxygen;
purging the non-radicalized oxygen and reaction byproducts from the process chamber; and
repeating the above exposing and purging steps until the metallic ruthenium nucleation layer thickness is at least 49 Å.

29. The method of claim 28 further comprising metalizing the through hole with copper wherein the copper is applied over the metallic ruthenium nucleation layer.
